(19) United States
(12) Patent Application Publication
(10) Pub. No.: US 2022/0187456 A1
(43) Pub. Date: Jun. 16, 2022

(54) DISTANCE MEASUREMENT SYSTEMS AND METHODS

(71) Applicant: OMRON CORPORATION, KYOTO (JP)

(72) Inventor: Fred Freybler Schleifer, Spencer, NY (US)

(21) Appl. No.: 17/598,776

(22) PCT Filed: Feb. 27, 2020
(86) PCT No.: PCT/US2020/020218

§ 371 Date: Sep. 27, 2021

Related U.S. Application Data
(60) Provisional application No. 62/826,666, filed on Mar. 29, 2019.

(51) Int. Cl. G01S 17/10; G01S 17/46; G01S 7/4861; G01S 7/4865

(52) U.S. Cl. CPC G01S 17/10; G01S 17/46; H03M 1/1235; G01S 7/4865; G01S 7/4861

(57) ABSTRACT

A laser scanner can include a light source to output laser pulses, and an optical sensor to generate analog signals, having a first dynamic range, from light of the laser pulses that is reflected by an object. A logarithmic amplifier can amplify the analog signals to have a second dynamic range that is smaller than the first dynamic range. An analog to digital converter can convert the analog signals to digital signal samples having a signal sample rate. A template can represent an expected return reflection signal, and can have a template sample rate that is higher than the signal sample rate. A processor can perform a cross-correlation between the digital signal samples and the template, determine a time-of-flight value based at least in part on the cross-correlation, and determine a distance to the object based at least in part on the time-of-flight value.

### CROSS-REFERENCE TO RELATED APPLICATIONS

This application claims the benefit under 35 U.S.C. § 119(e) of U.S. Provisional Patent Application No. 62/826,666, filed Mar. 29, 2019, and titled DISTANCE MEASUREMENT SYSTEMS AND METHODS. The entirety contents of the above-identified application(s) are hereby incorporated by reference herein and made part of this specification for all that they disclose.

### INCORPORATION BY REFERENCE

The entire contents of U.S. Pat. No. 6,753,776, issued Jun. 22, 2004, and titled PRESENCE SENSING SYSTEM AND METHOD, is hereby incorporated by reference herein and made part of this specification for all that it discloses.

### BACKGROUND

### Field of the Disclosure

Some embodiments disclosed herein relate to determining a presence of an object and/or a distance to an object, such as using a laser scanner or other optical device.

### Description of the Related Art

Although various systems exist for measuring a distance to an object, there remains a need for improved systems.

### SUMMARY

Certain example embodiments are summarized below for illustrative purposes. The embodiments are not limited to the specific implementations recited herein. Embodiments may include several novel features, no single one of which is solely responsible for its desirable attributes or which is essential to the embodiments.

Various embodiments disclosed herein can relate to a laser scanner, which can include a laser light source configured to output laser pulses, and an optical sensor configured to generate analog signals from light of one of the laser pulses that is reflected by an object. The analog signals can have a first dynamic range. A logarithmic amplifier can be configured to amplify the analog signals to have a second dynamic range that is smaller than the first dynamic range. An analog to digital converter can be configured to convert the analog signals to digital signal samples having a signal sample rate. A computer-readable memory can have a template stored therein. The template can represent an expected return reflection signal. The template can have a template sample rate that is higher than the signal sample rate. At least one processor can be configured to perform a cross-correlation between the digital signal samples and the template, determine a time-of-flight value based at least in part on the cross-correlation, and determine a distance to the object based at least in part on the time-of-flight value.

The optical sensor can be an avalanche photo diode. The laser scanner can have a capacitor between the optical sensor and the logarithmic amplifier. The capacitor can be configured to attenuate direct current (DC) components of the analog signals. An antialiasing filter can be configured to attenuate frequency content of the analog signals, such as above a threshold frequency. The at least one processor can be configured to convert the digital signal samples from a logarithmic scale to a linear scale. The signal sample rate can be between about 200 million samples per second and about 1,250 million samples per second. The signal sample rate is between about 200 million samples per second and about 600 million samples per second. The scanner can be configured to determine the distance to the object with a resolution of about 5 mm to about 75 mm. The signal sample rate can be less than 750 million samples per second, and the scanner can be configured to determine the distance to the object with a resolution of less than about 100 mm.

The at least one processor is configured to determine that an object is present at a first distance in response to a detection of light over a first light detection threshold, determine that an object is present at a second distance in response to a detection of light over a second light detection threshold, and determine that an object is present at a third distance in response to a detection of light over a third light detection threshold. The second distance can be further than the first distance. The third distance can be further than the second distance. The second light detection threshold can be higher than the first light detection threshold. The third light detection threshold can be lower than the second light detection threshold. The at least one processor can be configured to determine that an object is present at least in part by applying different light detection thresholds for different distances or distance ranges. The at least one processor can be configured to scale at least some of the digital signal samples based at least in part on the determined distance to the object. The at least one processor can be configured to confirm or disregard the presence of the object based at least in part on a comparison of the scaled digital signal samples to a threshold. The at least one processor is configured to determine that the object is potentially present at the determined distance, scale at least some of the digital signal samples based at least in part on the determined distance, and confirm the presence of the object at least in part by comparing the scaled digital signal samples to a threshold. The at least one processor can be configured to apply a first gain to the at least some of the digital signal samples for a first distance, apply a second gain to the at least some of the digital signal samples for a second distance, and apply a third gain to the at least some of the digital signal samples for a third distance. The second distance can be further than the first distance. The third distance can be further than the second distance. The second gain can be less than the first gain. The third gain can be more than the second gain.

The at least one processor can include a field programmable gate array and a microcontroller. The laser scanner can have a test signal generator configured to inject an analog test signal before the logarithmic amplifier, so that the logarithmic amplifier amplifies the analog test signal, and so that the analog to digital converter converts the analog test signal into a plurality of digital test signal samples. The at least one processor can be configured to analyze the plurality of digital test signal samples to validate the laser scanner. The at least one processor can be configured to perform a Fourier transform on the digital test signal samples to convert the digital test signal samples to the frequency domain. The at least one processor can be configured to analyze the frequency content of the digital test signal samples. The at least one processor can be configured to compare signal energy at a fundamental frequency to signal energy at one or more harmonic frequencies to analyze the digital test signal samples. The laser scanner can have an optical filter, which can be configured to permit the light of one of the laser pulses reflected by the object to be transmitted to the optical sensor. The optical filter can be configured to impede transmission of other wavelengths of light. The laser scanner can have a window. The laser light source can output the laser pulses through the window. The light of one of the laser pulses that is reflected by the object can be received through the window. The window can be configured to impede transmission of ambient light or of light having wavelengths not close to the laser light source.

Various embodiments disclosed herein can relate to a method for determining a distance to an object. The method can include emitting a light pulse in a direction towards an object, receiving a return reflection of the light pulse from the object, generating an analog signal for the return reflection using an optical sensor, amplifying the analog signal using a logarithmic amplifier, filtering the analog signal using an antialiasing filter, converting the analog signal to a plurality of digital signal samples at a signal sample rate, performing a cross-correlation between the plurality of digital signal samples and a template that has a template sample rate that is faster than the signal sample rate, and determining a distance to the object based at least in part on the cross-correlation.

Determining the distance to the object can include determining a time-of-flight value based at least in part on the cross-correlation and determining the distance to object based at least in part on the time-of-flight value. The method can include determining a return reflection arrival time based at least in part on the cross-correlation, determining a time-of-flight based at least in part on the return reflection arrival time and a time that the light pulse was emitted, and determining the distance to the object based at least in part on the time-of-flight. The method can include converting the plurality of digital signal samples from a logarithmic scale to a linear scale prior to the cross-correlation. The cross-correlation can be performed by a processor. The processor can be in communication with computer-readable memory that stores the template. The method can include stopping machinery in response to detecting an object. The method can include determining the distance to the object with a resolution between about 10 mm and about 50 mm. The light pulse can be a laser pulse.

The method can include confirming the presence of the object at least in part by scaling at least some of the digital signal samples based at least in part on the determined distance and comparing the scaled digital signal samples to a threshold. Scaling the at least some of the digital signal samples can have the effect of increasing sensitivity in a short range as compared to a mid range. The scaling can have the effect of increasing sensitivity in a long range as compared to the mid range. The method can include applying different light detection thresholds for different distance ranges to determine presence of an object. The method can include comparing light reflected from a first distance to a first light detection threshold to determine whether an object is present at the first distance, comparing light reflected from a second distance to a second light detection threshold to determine whether an object is present at the second distance, and comparing light reflected from a third distance to a third light detection threshold to determine whether an object is present at the third distance. The second distance can be further than the first distance. The third distance can be further than the second distance. The second light detection threshold can be higher than the first light detection threshold. The third light detection threshold can be lower than the second light detection threshold.

The method can include injecting an analog test signal, amplifying the analog test signal using the logarithmic amplifier, filtering the analog test signal using an antialiasing filter, converting the analog test signal to a plurality of digital test signal samples, and analyzing the plurality of digital test signal samples for validation. The method can include analyzing the plurality of digital test signal samples in the frequency domain. The method can include performing a Fourier transform on the plurality of digital test signal samples.

Various embodiments disclosed herein can relate to a laser scanner, which can include a laser light source configured to output laser light, an optical sensor for generating analog signals from return reflections of the laser light that is reflected by objects, an analog to digital converter configured to convert the analog signals to digital signal samples, and a processor configured to process the digital signal samples to determine time-of-flight information.

The laser scanner can include an amplifier for amplifying the analog signals. The amplifier can be a logarithmic amplifier. The processor can be configured to convert the digital signal samples from a logarithmic scale to a linear scale. The amplifier can have a soft saturation characteristic. The processor can be configured to compare the digital signal samples to a template. The time-of-flight information can be based at least in part on the comparison. The comparison can be a cross-correlation. The processor can be configured to determine a distance to the object based at least in part on the time-of-flight information.

Various embodiments disclosed herein can relate to a laser scanner, which can include an optical sensor configured to generate analog signals and an analog to digital converter configured to convert the analog signals to digital signal samples. The digital signal samples can have a signal sample rate between about 200 million samples per second and about 600 million samples per second. A processor can be configured to analyze the digital signal samples to determine a distance to an object with a distance resolution of about 5 mm to about 75 mm.

### BRIEF DESCRIPTION OF THE DRAWINGS

Certain embodiments will be discussed in detail with reference to the following figures, wherein like reference numerals refer to similar features throughout. These figures are provided for illustrative purposes and the embodiments are not limited to the specific implementations illustrated in the figures.

FIG. 1 shows an example embodiment of a laser scanner configured for guarding hazardous equipment.

FIG. 2 is a block diagram showing components of an example embodiment of laser scanner.

FIG. 3 shows a perspective view of an example embodiment of a laser scanner.

FIG. 4 shows a cross-sectional view of another example embodiment of a laser scanner.

FIG. 5 is a block diagram showing an example embodiment of a detection system for a laser scanner.

FIGS. 6A-6F show comparisons of a template with plots of digital signal samples.

FIG. 6G shows example template waveforms.

FIG. 7 is a flowchart of an example method for determining a distance to an object.

### DETAILED DESCRIPTION OF CERTAIN EMBODIMENTS

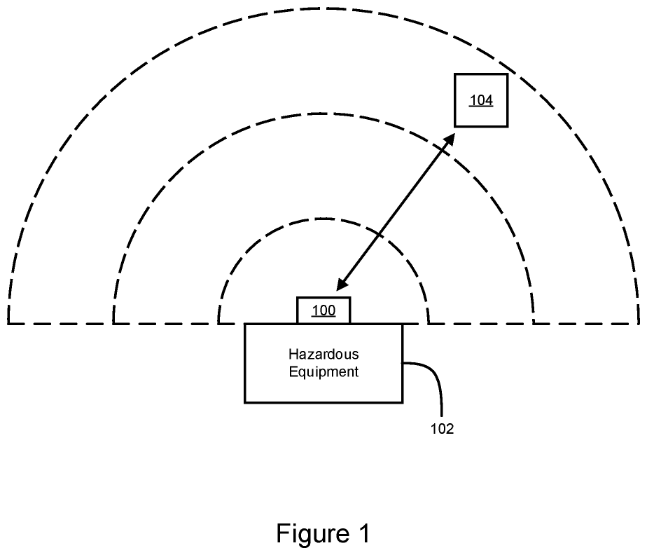

Laser scanners or other systems for sensing the presence of an object and/or for measuring a distance to an object can be used in various applications, such as for guarding hazardous equipment (e.g., industrial machinery), for surveying, for security systems, for robot vision, robot guidance or pathfinding, etc. FIG. 1 shows a laser scanner 100 configured for guarding hazardous equipment 102 (e.g., such as industrial machinery). Although various examples are provided herein with relation to laser scanners for machine guarding, the features and concepts disclosed herein can be applied to various other contexts such as range finders, surveying equipment, light curtains, motion detectors, navigation systems, autonomous vehicles, etc. A laser scanner 100 can emit a pulse of light and receive light reflected from an object 104, which can be measured and used to determine that the object 104 is present. In some applications, the laser scanner 100 can send pulses of light in multiple directions so that the direction to the object can be determined. For example, the laser scanner 100 can step light pulses across an angular field of view, such as at sub-degree increments, although other increments or other configurations could be used, depending on the application. The laser scanner 100 can determine a distance to the object 104, such as by determining a time-of-flight for the light to travel to the object and then back to the laser scanner 100. For example, the distance to the object can be ½·c·t, where c is the speed of light, and t is the time-of-flight. Using the direction and distance information, the location of the object 104 can be determined. Action can be taken in response to the determination of the location, direction, and/or distance of the object. For example, the hazardous equipment 102 can be stopped if an object 104 (e.g., a person) comes within a threshold distance, or an alarm or warning can be issued, etc.

Because light travels rapidly, the precision of the time-of-flight measurement can have a significant effect on the distance determination. For example, one nanosecond difference in the time-of-flight can result in a 150 mm difference in distance. Also, the resolution of the distance determination can depend on the sampling rate. For example, a sampling period of 2 nanoseconds (e.g., sampling frequency of 500 MHz) can result in a native distance resolution increments of 300 mm. According, in this example, the laser scanner would be able to determine the distance to the object in increments of 300 mm. Increasing the sampling rate of the laser scanner 100 can be expensive. Various embodiments disclosed herein relate to upsampling to increase the effective sampling rate of the laser scanner 100 to thereby increase the resolution of the distance determination (e.g., in a cost effective manner).

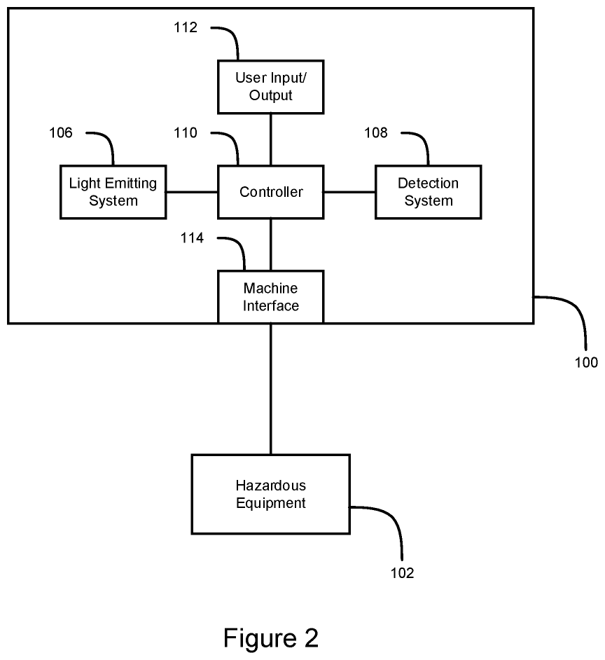

FIG. 2 is a block diagram showing components of an example embodiment of a laser scanner 100. The laser scanner 100 can have a light emitting system 106, which can be configured to emit light, such as by producing pulses of light. The light emitting system 106 can have a laser, such as a pulse laser that is configured to output discrete laser pulses. The duration of the light pulses (e.g., the laser pulse width) can also affect the resolution of the distance determination. For example, in some cases, increasing the actual sampling rate can have diminishing returns for increasing the distance resolution if the light pulses are not fast enough. Faster lasers, e.g., that produce laser pulses with shorter pulse widths, can be expensive. Some embodiments disclosed herein can relate to upsampling to effectively increase the sampling rate to increase the resolution of the distance measurement while using cost effective lasers and other components.

The laser scanner 100 can have a detection system 108 that can be configured to receive light (e.g., of the laser pulses) that is reflected from the object 104 back to the laser scanner 100. The laser scanner 100 can have a controller 110 configured to control operations of the laser scanner 100, as described herein. The controller 110 can include one or more hardware processors, and can execute instructions that are stored in computer-readable memory (e.g., in a non-transitory computer readable medium). The laser scanner 100 can have a machine interface 114, which can output instructions to corresponding hazardous equipment 102 (e.g., industrial machinery) or other external devices. For example, the laser scanner can stop the machinery or move the machinery to a safety configuration if an object (e.g., a person) is detected at a specified location or distance, etc. Other output signals can also be provided, such as for warnings or alarms or data logging, etc.

The laser scanner 100 can have input/output features 112. For example, user input elements (e.g., one or more buttons, dials, switches, microphone, etc.) can be used to receive input from a user. User output elements (e.g., one or more lights, speakers, displays, printers, etc.) can be used to output information to a user. In some cases, user input and output elements can be combined, such as using a touchscreen display. The input and output elements 112 can be used to configure, operate, and/or troubleshoot the laser scanner 100. The output elements 112 can provide presence, direction, distance, and/or location information regarding an object. By way of example, the laser scanner 100 can have multiple lights, which can be selectively illuminated to indicate a direction of an object. Different colors, light intensity, or numerical values can be output to indicate a distance of a detected object from the scanner 100. The laser scanner 100 can output a first color of light (e.g., green) for a safe condition (e.g., in which no object is determined to be in a dangerous location or range) and can output a second color of light (e.g., red) for a danger conduction (e.g., in which an object is determined to be in a dangerous location or range). Many alternatives are possible.

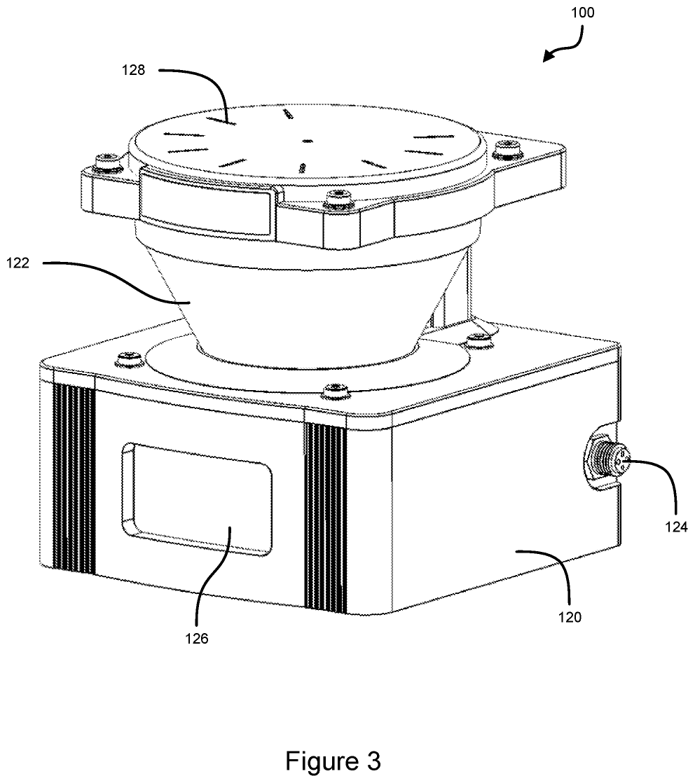

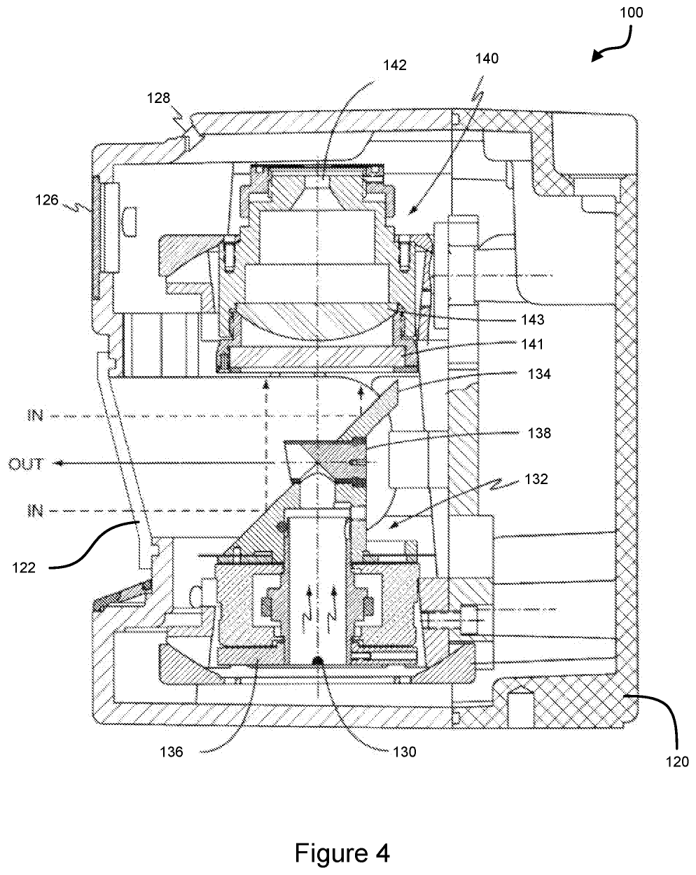

FIG. 3 is a perspective view of an example embodiment of a laser scanner 100. FIG. 4 is a cross-sectional view of another example embodiment of a laser scanner 100. The laser scanner 100 can have a housing 120, which can enclose or otherwise protect various components of the laser scanner 100, such as electrical and/or optical components. The laser scanner 100 can have a window 122, which can enable light (e.g., from the light emitting system 106) to exit the laser scanner 100 and/or can enable light (e.g., reflected from the object 104) to enter the laser scanner 100, so that the received light can be detected by the detection system 108.

A port 124 can receive a corresponding plug to transfer information to or from the laser scanner 100, such as to implement the machine interface 114. Information can be communicated through a wired connection (e.g., via the port 124), or the scanner 100 can have a wireless communication system for sending and/or receiving information wirelessly. A power cable (which not visible in FIGS. 2 and 3) can supply power to the laser scanner 100, although other types of power sources can be used, such as a battery. The laser scanner 100 can have a display 126 which can output information and/or receive user input (e.g., a touchscreen). The display 126 can display text, images, or in some cases can display light colors or patterns (e.g., green, red, flashing, etc.) to indicate information to a user. In some embodiments, a plurality of light indicators 128 can be illuminated to indicate a direction of a detected object, or to output other information.

The scanner 100 can have a light source, such as a laser light source 130, which can emit light (e.g., laser pulses). The light source 130 can be a pulse laser (e.g., an NIR pulse laser). The pulse laser can output laser pulses, such as with a pulse width of about 1 ns, about 2 ns, about 3 ns, about 3.5 ns, about 4 ns, about 5 ns, about 6 ns, about 7 ns, about 8 ns, about 10 ns, or any values or ranges therebetween, although pulse widths outside these ranges could also be used in some cases. In some embodiments, a continuous wave laser, or various different types of light sources, could be used. In some cases, a pulse laser can provide good signal energy and signal to noise ratio. One or more optical elements 132 can redirect the light out of the laser scanner, or otherwise modified the emitted light. The optical elements 132 of the light emitting system 106 can include one or more lenses, filter, mirrors, etc. which can modify or redirect the light. In some cases, a collimator (e.g., a collimating lens) can be used to collimate light emitted by the light source 130. Although some examples are discussed in connection with a laser scanner, in some cases the scanner 100 can use non-laser light, which can be collimated in some implementations. The scanner 100 can include a rotatable mirror 134, which can redirect the light out of the scanner 100 at different azimuthal angles depending on the rotational position of the rotatable mirror 134. The rotatable mirror 134 can be angled relative the path of the emitted light that impinges on the rotatable mirror 134 (e.g., by an angle between about 30 degrees and about 60 degrees, about 40 degrees and about 50 degrees, or about 45 degrees). A motor 136 can rotate the rotatable mirror 134 (e.g., about a vertical rotation axis). Light (e.g., laser pulses) can be emitted through the window 122. The window can have a generally inverted frustoconical shape. The window can extend across about 90 degrees, about 120 degrees, about 150 degrees, about 180 degrees, about 210 degrees, about 240 degrees, about 270 degrees, about 300 degrees, about 330 degrees, or more, or any values or ranges therebetween. The scanner 100 can sweep or step laser pulses across a field of view or detection area, such as across and angle of about 90 degrees, about 120 degrees, about 150 degrees, about 180 degrees, about 210 degrees, about 240 degrees, about 270 degrees, about 300 degrees, about 330 degrees, or more, or any values or ranges therebetween. A turning mirror 138 can redirect light from the light source 130, such as to help turn or redirect the light out of the scanner 100.

Light can be reflected from an object and reflected light can return to the laser scanner 100. Return reflections of the emitted light can be received through the window 122. One or more optical elements 140 can redirect the received light and/or otherwise modify the received light before it is measured by an optical sensor 142. The one or more optical elements 140 can include one or more lenses 143, filters 141, mirrors, etc. The optical sensor 142 can generate signals based at least in part on the light reflected by the object and received by the laser scanner 100. The rotatable mirror 134 can direct the received light towards the optical sensor 142. The optical sensor 152 can be a photodiode such as an avalanche photodiode, although any suitable type of image sensor can be used. The image sensor 142 can convert the received light to electrical signals. The scanner 100 can analyze the electrical signals to determine the presence, direction, distance, and/or location of an object 104. The laser scanner 100 can utilize the additional details and features disclosed in the '776 patent, which is incorporated herein by reference.

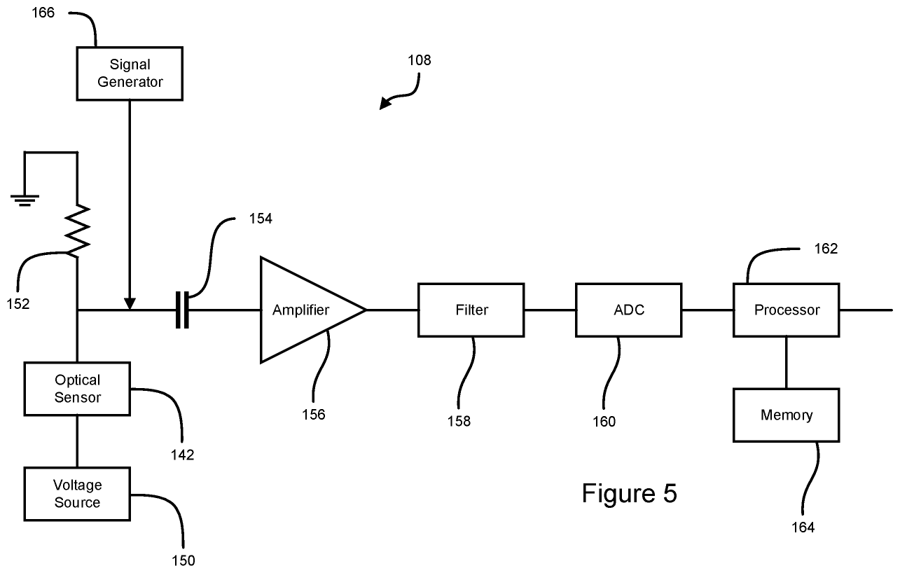

FIG. 5 is a block diagram showing an example embodiment of a detection system 108 for a laser scanner. The detection system 108 can have an optical sensor 142, an AC-coupling capacitor, an amplifier 156, a filter 158, an analog-to-digital converter (ADC) 160, a processor 162, and computer-readable memory 164.

In some embodiments, the optical sensor 142 can be an avalanche photodiode, although any suitable type of optical sensor could be used. The avalanche photodiode can convert light that it receives to electricity using the photoelectric effect. The avalanche photodiode can have a relatively high bias voltage (e.g., between about 80 volts and about 300 volts, although any suitable voltage can be used), such as received from a voltage source 150 (e.g., a power supply or battery). The optical sensor 142 can be coupled through a resistor 152 to ground. In some embodiments, an active current source or load can be used instead of a resistor 152. The optical sensor 142 can produce analog signals in response to light received by the laser scanner 100. The analog signals can correlate to or otherwise indicate an amount of light or an intensity of light received by the optical sensor 142. The analog signals can be delivered to additional components through a node or connection between the optical sensor 142 and the resistor 152, or between the optical sensor 142 and ground. Various other configurations are possible, such as for other types of optical sensors 142. In some cases, one or more of the voltage source 150, resistor 152, and/or ground shown in FIG. 5 can be omitted.

The analog signals can be provided through a capacitor 154 to the additional components (e.g., the amplifier 156 and/or ADC 160, as discussed herein). The capacitor 154 can be an AC-coupling capacitor. The capacitor can be configured to attenuate direct current (DC) components of the analog signals while permitting alternating current (AC) components of the analog signals to pass through to the capacitor 154 towards the ADC 160 or other intervening components. The capacitor 154 can block some signals that can correspond to constant ambient light received by the laser scanner 100. The capacitor 154 can be a parallel plate capacitor or any other suitable type of capacitor.

The analog signals (e.g., output by the optical sensor 142) can be amplified by an amplifier 156. The amplifier 156 can be a logarithmic amplifier, which can convert the analog signals to a logarithmic scale. The logarithmic amplifier 156 can compress or reduce the dynamic range of the analog signals. For example, the logarithmic amplifier 156 can receive analog signals having a first dynamic range (e.g., from the optical sensor 142), and the logarithmic amplifier 156 can output analog signals having a second dynamic range, which can be narrower than the first dynamic range. This can enable the ADC 160 to encode a wide dynamic range of analog signals using a limited number of bits, as discussed herein. Modifying the dynamic range of the analog signals prior to the ADC 160 can impede saturation when the analog signals are converted to digital signals. Modifying the dynamic range can improve ranging accuracy by reducing the effect of low-level tails in the laser pulse waveform and/or the optical sensor output. In some embodiments, other types of amplifiers or other techniques can be used to modify the dynamic range. For example, the amplifier can have a soft-saturation characteristic, which can be used to improve the dynamic range.

In some embodiments a filter 158 can modify the analog signals. For example, the filter 158 can be an antialiasing filter. The filter 158 can attenuate higher frequencies (e.g., above a threshold frequency) while passing lower frequencies (e.g., below a threshold frequency). The filter 158 can be a low-pass filter. The filter 158 can attenuate frequencies above about half the sampling rate (e.g., of the ADC 160), for example. In some cases, the filter 158 and the DC attenuation feature (e.g., the AC-coupling capacitor 154) can be combined, such as using a bandpass filter. The filter 158 can be a third order, fifth order, or seventh order anti-aliasing filter, although other filters could be used, e.g., at intermediate values or ranges.

The ADC 160 can convert the analog signals (e.g., from the optical sensor 142 or as modified by intermediate components) to digital signals. The ADC 160 can be an 8-bit ADC, although any other suitable number of bits can be used, such as 4, 6, 8, 10, 12, 14, 16 bits, or more, or any values or ranges therebetween. The logarithmic amplifier 156 can enable an increased dynamic range to be encoded by the ADC, using a limited number bits, such as using a cost-effective ADC.

The ADC 160 can have a sampling rate of about 150 million samples per second (Msps), about 200 Msps, about 250 Msps, about 300 Msps, about 350 Msps, about 400 Msps, about 450 Msps, about 500 Msps, about 550 Msps, about 600 Msps, about 650 Msps, about 700 Msps, about 750 Msps, about 800 Msps, about 900 Msps, about 1,000 Msps, about 1,250 Msps, about 1,500 Msps, about 1,759 Msps, about 2,000 Msps, about 2,500 Msps, about 3,000 Msps, or more, or any values therebetween, or any ranges bounded by these values, although other sampling rates can also be used. The ADC 160 can produce a digital signal every 2 nanoseconds for sampling rate of 500 Msps, for example. ADCs 160 with lower sampling rates can be more cost effective. However, a low native sampling rate can result in poor resolution for the distance determinations, as discussed herein. In some embodiments, digital signal processing can be performed to upsample the digital signals to produce an increased effective sampling rate, which can increase the distance resolution. An upsampling correlator can be used. The upsampling can use zero insertion, which can be efficient and can avoid undesired filter response.

The processor 162 can be a field programmable gate array (FPGA), a general purpose hardware processor, an application-specific integrated circuit (ASIC), or any other suitable hardware for performing the functions described herein. In some embodiments the processor 162 can be in communication with computer readable memory 164 (e.g., non-transitory computer-readable medium). In some embodiments, the processor 162 can execute instructions stored in the memory 164 to perform the functions described herein. The processor 162 can be a digital signal processor. The processor 162 can perform digital signal processing to determine a time-of-flight value, a distance to an object, and/or a presence or location of an object, etc. In some embodiments, the correlation template can reside in on-chip memory in the FPGA. The FPGA can include volatile memory, in some cases, and the template can be configured during system initialization. In some cases, the template can be stored in non-volatile memory.

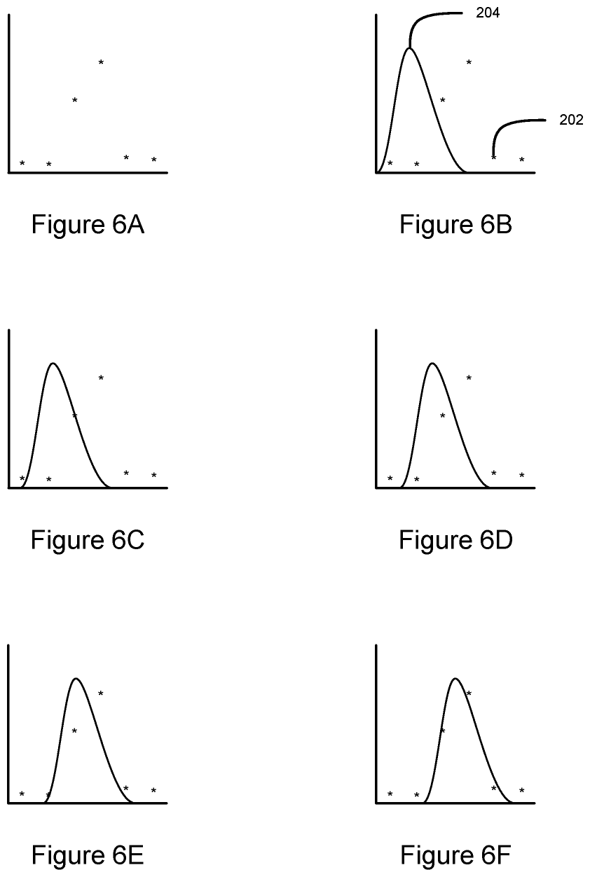

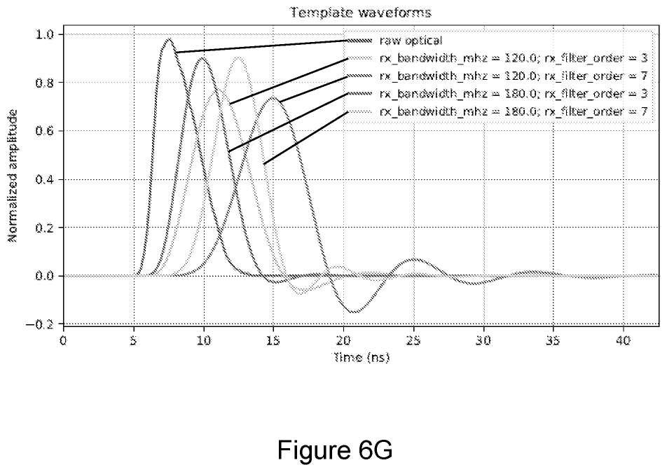

The processor 162 can perform a comparison between the digital signal samples and a template. For example, the processor 162 can perform a cross-correlation between the digital signal samples and the template. FIGS. 6A to 6F show an example of a cross-correlation operation between digital signal samples 202 (shown by * on the plots) and a template 204. The template 162 can include discrete values or a continuous function. In some cases, the discrete values of the template 204 can have spacing therebetween that is shorter than the spacing between the digital signal samples 202 (e.g., from the ADC 160). The template can have a template sampling rate that is faster than the signal sampling rate (e.g., as set by the ADC 160). For example, the template can have a sample rate that is about 2 times, about 4 times, about 5 times, about 7 times, about 10 times, about 12 times, about 15 times, about 17 times, about 20 times, about 22 times, about 25 times, about 30 times, about 40 times, or about 50 times higher than the signal sampling rate (e.g., which can be set by the ADC 160), or any values therebetween, or any ranges bounded therein, although other sample rates can be used. In some cases the template 204 can be stored as a table or set of values. In some cases the template 204 can be stored as a formula, equation, or function, etc.

FIG. 6A shows an example plot having a plurality of digital signal samples 202. The x-axis can correspond to time. The y-axis can correspond to intensity or amount of light (e.g., received by the optical sensor 142). Because of the sampling rate of the ADC 160 (e.g., 500 Msps, or one sample every 2 nanoseconds), there are gaps between the digital signal samples 202. FIG. 6A shows the same sample digital signal samples 202, with the template 204 at a first position. For the cross-correlation, the correlation between the template 204 and the digital signal samples 202 can be determined for multiple locations as the template is stepped across the digital signal samples 202 as shown in FIGS. 6B to 6E (or as the digital signal samples are stepped across the template 204). The processor 160 can determine the location where the template 204 best correlates or most matches the digital signal samples 202, which is shown in FIG. 6F. Several intermediate increments can be used, but are omitted from the figures for simplicity.

The correlation can be evaluated at steps that correspond to the template sample rate. For example, for a sample rate of 10 giga-samples-per-second, the template 204 can be stepped and compared to the signal samples 202 at increments of 0.1 nanoseconds, although other increments can be used. As can be seen in FIGS. 6A-6F, by performing the cross-correlation between the template 204 and the signal samples 202, the time of receipt of the return reflection of the laser pulse can be more precisely determined, as compared to other techniques, such as merely comparing the signal samples 202 to a threshold light value. For example, as shown in FIG. 6F, by performing the cross-correlation it can be determined that the peak of the return reflection of the laser pulse was received at a time between the third and fourth plotted signal samples. In contrast, if the signals 202 of FIG. 6A were merely compared against a threshold, the return reflection light would either be determined to arrive at the time of the third or fourth plotted samples (e.g., depending on the value that the threshold is set at). Accordingly, by performing the cross-correlation, or other type of comparison, between the signals 202 and the template 204, the digital signals can be up-sampled to have a faster effective sampling rate.

By using a template 204 with sufficient resolution or a sufficiently high template sample rate and/or by stepping the template 204 and/or the digital signal samples 202 at sufficiently short increments, the arrival time of the return reflection, the time-of-flight, and/or the associated object distance can be determined with improved accuracy. For example, using a template 204 with a template sample rate of 10 giga-samples-per-second, and by stepping the template 204 at increments of 0.1 nanoseconds, the arrival time of the return reflection (e.g., the peak or other identifiable feature thereof) can be determined with about 0.1 nanosecond resolution, instead of the 2 nanosecond resolution that could result from direct analysis of the 500 Msps digital signal samples from the ADC 160. By way of this example, the distance to an object 104 can be determined with a distance resolution of about 15 mm, rather than about 300 mm. The distance can be determined with a resolution of about 5 mm, about 7 mm, about 10 mm, about 12 mm, about 15 mm, about 17 mm, about 20 mm, about 25 mm, about 30 mm, about 35 mm, about 40 mm, about 45 mm, about 50 mm, about 55 mm, about 60 mm, about 65 mm, about 70 mm, about 75 mm, about 80 mm, about 85 mm, about 90 mm, about 95 mm, about 100 mm, or any values therebetween, or any ranges bounded by any combination of these values, although other values could also apply. In some cases, the distance resolutions can be determined with a 5 sigma confidence level, although other confidence levels could also apply (e.g., depending on the laser power and noise, etc.).

Using the amplifier 156 (e.g., logarithmic amplifier) to impede saturation and to cover an increased dynamic range can be beneficial in providing digital signals that accurately depict the amount of light received by the optical sensor 142, which can facilitate the cross-correlation operation. For example, if the amplifier 156 were omitted and the digital signals were saturated for some of the digital signals that correspond to the return reflection of the light pulse, then it would be more difficult to accurately perform the cross-correlation with the template. The saturated digital signals could be sufficient for a system that merely compares the digital signals to a threshold, because that determination would not be affected by how much light over the threshold amount was received. However, the precise amount of light received for each signal sample can improve the accuracy of the cross-correlation. Therefore, using the logarithmic amplifier (or otherwise improving the dynamic range) can have a synergistic effect when combined with the template comparison technique disclosed herein.

The relatively small number of digital signal samples 202 compared to the template 204 can result in processing efficiency when making the comparison (e.g., cross-correlation). For example, in FIGS. 6B to 6F, there are 6 digital signal samples. By way of example, each increment of the cross-correlation may involve 6 operations for comparing the 6 digital signal samples to corresponding portions of the template. Due to the relatively small number of digital signal samples, the cross-correlation for each increment can be performed quickly, and a large number of increments can be performed using a cost-effective processor, which can provide surprisingly good distance resolution for the cost.

The template can be stored in the computer-readable memory 164. The processor 162 can obtain the template from memory 164 and can compare the template to the digital signals. The template can have the shape or values of an expected return reflection of a light pulse output by the light emitting system 106. For example, if longer laser pulses were used, a longer template shape that extends further along the x-axis could be used. The template can be configured to correspond to one or more of the following: the type of light source 130, the one or more optical elements 132 that modify the emitted light, parameter(s) of the emitted light pulses, the one or more optical elements 140 that modify the received light, and/or one or more analog signal processing features (e.g., the logarithmic amplifier 156 or filter 158). For example, the template can omit portions of the signal tails if the filter 158 is configured to filter off those portions of the tails of the analog signals. Similarly, the template can be in a logarithmic or linear scale, depending on the scale of the digital signals used for the comparison. For example, in some cases, the logarithmic amplifier can convert the analog signals to a logarithmic scale, and the associated converted digital signals can maintain that logarithmic scale. The template can also have a logarithmic scale and the cross-correlation, or other comparison, can be done in the logarithmic scale. Alternatively, the processor 162 can convert the digital signals from the logarithmic scale to a linear scale. For example, an inverse function of the logarithmic amplifier can be applied to the digital signals. Accordingly, the cross-correlation, or other comparison, can be performed in the linear scale. Various other types of conversions of the signals are possible. The scanner 100 can use a nonlinear amplifier followed by a linear ADC, which can provide a relatively large number of quantization steps, as compared to some other approaches.

The intensity of reflected light received by the scanner 100 can vary, such as depending on the distance to the object, the size of the object, the shape, color, and/or reflectivity of the object, etc. In FIG. 6F, the amplitude of the digital signals is about the same at the template amplitude. However, in some cases, the amplitude of the digital signal can be significantly lower than the template amplitude. For example, the template can be based at least in part on an ideal expected reflectance (e.g., no merged pulses or noise), and the digital signals can represent the actually received reflected light, which may be less than the ideal expected amount. The cross-correlation can be performed to find the time that the template best aligns with the digital signals, even if the amplitudes are significantly different. The template can have a width (full width half height) of less than about 20 nanoseconds, less than about 15 nanoseconds, less than about 10 nanoseconds, less than about 5 nanoseconds, less than about 3 nanoseconds, less than about 2 nanoseconds, or any values therebetween or ranges bounded therein, although other template widths could be used, such as depending on the laser pulse width. The template can have tails in some embodiments. Various template shapes can be used, depending on the application. The correlation can be performed based on the amplitude samples of the receiver waveform. The template correlation can be a form of finite impulse response (FIR) filtering.

FIG. 6G shows some examples of template waveforms, which are shown superimposed. In some cases, the template waveform can have some ring or oscillation, which can dip below the baseline, such as when a higher-order anti-aliasing filter is used. In some cases, the digital signal samples and/or the template can have at least some portion with negative values (e.g., after removal of the DC offset). This can be a result of the anti-aliasing filtering. The shape of the template 204 can be made to resemble the raw signal expected from a return reflection. The shape of the template 204 can be made to resemble the filtered and/or amplified signal expected from a return reflection.

With reference again to FIG. 5, in some embodiments, the processor 162 can provide a sample clock to the ADC 160, which can be used for setting the sampling rate of the ADC 160. In some cases, a clock signal can be from a different source. For example, an external master clock can send clock signals to the ADC 160 and/or to any other suitable components. The ADC 160 and the processor 162 can be different integrated circuits, although these or other components could be integrated into a single integrated circuit.

In some cases, the processor 162 can output a return reflection arrival time, a time-of-flight value, a distance to a detected objection, and/or a presence detection of an object. In some cases, the processor 162 can output information to a separate controller 110. For example, the processor 162 can perform the signal processing and determine time-of-flight information, which can be delivered to the controller 110. The controller 110 can then determine a distance to the object based on the time-of-flight information, and whether to take action (e.g., to stop a piece of machinery). In some cases, the processor 162 and the controller 110 can be implemented on the same hardware processor. The processor 162 can be the same component as the controller 110. Where multiple processors are used, any combination of tasks or division of labor can be used for the multiple processors.

In some cases, the scanner 100 can have optical sensitivity that varies with range. For example, the scanner 100 can be more sensitive to light in a mid-range than in a close-range or a far-range. Accordingly, false positives for object detection can be more likely in the mid-range where the scanner has higher optical sensitivity. For example, floating dust can reflect small amounts of light, which can cause the scanner 100 to determine that an object is present. In some cases, the optics can be focused or optimized for the mid-range region. In some cases, the optics can be configured to suppress reflections off the window at close range, and this can result in some suppression of other close-range reflections. In some cases portions of the scanner can occlude or block some light for the close-range. For the far-range, the distance that the light travels can result in less light reaching the scanner, which can result in reduced sensitivity. The scanner 100 can apply different light detection thresholds at different ranges, which can at least partially compensate for the differences in sensitivity. For example, at a first distance in a close-range, the scanner can apply a first light detection threshold. For a second distance in a mid-range, the scanner can apply a second light detection threshold, which can be higher than the first light detection threshold. For a third distance in a far-range, the scanner can apply a third light detection threshold, which can be lower than the second light detection threshold. A particular light detection threshold can be applicable across all distances in a range (e.g., close-range, mid-range, or far-range). Or a formula, equation, or function, or lookup table can define a varying light detection threshold based on the distance. Although some examples describe first, second, and third thresholds, the scanner can apply any number of different thresholds (e.g., many more than three thresholds) depending on the determined distance of the potential object.

In some implementations, the scanner 100 (e.g., via the signal processor 162 and/or the controller 110) can scale the signal based at least in part on the determined distance. The same threshold can be applied for different distances or ranges, and the differences in sensitivity based on distance can be a result of the signal scaling. For example, the scanner 100 can adjust the amplitude of the signal based at least in part on the determined distance. The scanner 100 can apply different amounts of gain to the signal based at least in art on the determined distance. By way of example, at a first distance in a close-range, the signal can be scaled by a first amount (e.g., a first amount of gain). For a second distance in a mid-range, the signal can be scaled by a second amount (e.g., a second amount of gain), which can be less than the first amount of scaling (e.g., the first amount of gain). For a third distance in a far-range, the signal can be scaled by a third amount (e.g., a third amount of gain), which can be more than the second amount of scaling (e.g., the second amount of gain). In some cases, the same amount of scaling (e.g., gain) can be applied to various distances in a range (e.g., close-range, mid-range, or far range). In some cases, a formula, equation, function, or lookup table can define varying amounts of scaling (e.g., gain) based on the distance. For example, a lookup table can have various multipliers assigned to various possible distances. If a possible object is at the first distance (e.g., in a relatively close range), a first multiplier (e.g., 1.5) can be applied to the digital signal values. If a possible object is at the second distance (e.g., in a relatively mid range), a second multiplier (e.g., 1.0) can be applied to the digital signal values. If a possible object is at the third distance (e.g., in a relatively long range), a third multiplier (e.g., 2.0) can be applied to the digital signal values. Various intermediate values can populate the lookup table. Although some examples discuss application of signal gain to perform the signal scaling, signal reduction could be applied (e.g., reducing mid-range signals more than close-range and/or long-range signals), or any other suitable form of signal scaling. Although some examples describe first, second, and third scaling amounts (e.g., signal gains), various different amounts of scaling can be applied depending on the determined distance to the potential object. The relationship between the distance and signal scaling can be fixed. Similarly, the relationship between the distance and the applicable threshold can be fixed.

If the scanner receives a small amount of light, it can first determine the distance to an object that may possibly be at that distance or location (e.g., using the distance determination techniques disclosed herein). The scanner can then apply an applicable light detection threshold based on the determined distance. A lookup table or formula can be used. The amount of received light (e.g., the amplitude of the digital signals 202) can be compared to the applicable light detection threshold to confirm whether an object is present at that distance or location associated with the small amount of light that was received. In some embodiments, the scanner can scale the signal representative of the amount of light received based on the determined distance. A lookup table or formula can be used, for example. The scaled signal can be compared to a threshold (e.g., a fixed threshold) to confirm whether an object is present at the distance or location associated with the small amount of light that was received.

Accordingly, in some cases, an amount of received light can trigger a determination that an object is present at a relatively far distance (e.g., a far-range), whereas the same amount of received light would not trigger a determination that an object is present at a closer distance (e.g., a mid-range). Also, in some cases, that same amount of light would trigger a determination that an object is present at a range that is closer still (e.g., a close-range).

In some embodiments, the optics or other parameters of the scanner 100 can be configured to reduce the variability in optical sensitivity, such as to provide a relatively flat optical sensitivity curve. However, by compensating for the different sensitivity at different distances, a less flat optical sensitivity curve can be tolerated, and some associated costs can be saved. In some embodiments, the presence determination can depend on the distance determination.

Various embodiments are discussed in connection with determining a reflection arrival time, a time-of-flight value, a distance to an object (or potential object), and an object presence. In some implementations, one or more of these intermediate determinations or calculations can be omitted. For example, the distance can be determined directly, without separately determining the time-of-flight value.

With reference again to FIG. 5, in some embodiments a test signal can be injected for testing or verifying the detection system. A signal generator 166 can inject an analog test signal so that the analog test signal is converted by the ADC 160 to digital test signals. The test signal can be injected before the capacitor 154, amplifier 156, and/or filter 158, or at any intermediate location between these elements. The processor 162 can analyze the resulting digital test signals to validate or test the scanner 100. The processor 162 can compare the digital test signals to expected digital test signals. If the actual and expected signals differ more than a threshold amount, the processor can determine that a malfunction has occurred between injecting the analog test signal and receiving the converted digital test signals. The expected digital test signals can be different than the injected analog test signals, such as to account for the changes to the test signals from the capacitor 154, the amplifier 156, the filter 158, and/or the conversion to digital by the ADC 160. In some cases, the digital signal can be compared to the original test signal for validating the scanner 100.

The capacitor 154 can attenuate a DC component of the analog test signal. The amplifier 156 can amplify the analog test signal (e.g., converting the analog test signal to a logarithmic scale). The filter 158 can attenuate portions of the analog test signal (similar to the discussion herein). The ADC 160 can convert the analog test signal to one or more digital test signals. The processor can analyze the one or more digital test signals in the logarithmic scale, or the digital test signals can be converted from a logarithmic scale to a linear scale for analysis by the processor 162. In some cases the processor can analyze the one or more digital test signals in the frequency domain or in the time domain. For example the processor 162 can perform a Fourier transform (e.g., a fast Fourier transform) to convert the digital test signals to the frequency domain. The frequency content of the converted signals can be analyze or compared to validate the scanner 100. For example, the validation or malfunction determination can be based at least in part on how much signal energy is at the fundamental frequency and how much is at the harmonics.

With reference again to FIG. 4, in some embodiments, the scanner 100 can include an optical filter 141 disposed along the return reflection optical path and before the optical sensor 142. The optical filter 141 can be configured to permit the light of the return reflections of the laser pulses to pass through the optical filter 141 and reach the optical sensor 142. The optical filter 141 can be configured to impede transmission of at least some types of other light (e.g., not from the light source 130) from reaching the optical sensor 142. The optical sensor 141 can impede light that would interfere with the light of the return reflections. The optical sensor 141 can be configured to impede ambient light. The optical sensor 141 can be configured to impede visible light. In some cases, multiple optical filters 141 can be combined (e.g., stacked in series) to impede various wavelengths of light. The optical filter 141 can impede light with a wavelength that is different from the wavelength of the light source 130 by at least a threshold amount. For example, the light source can be an NIR laser with a wavelength of about 905 nm. The optical filter 141 can substantially permit light having a wavelength between about 880 nm to about 925 nm to pass through the optical filter 141, while substantially impeding light below about 880 nm or above about 925 nm. Many different wavelengths, ranges, and thresholds could be used. In some cases, the threshold or light-impeding properties of the optical sensor 141 for light below the light source wavelength can be different than for light above the light source wavelength. Modifying the above example, the optical filter 141 could impede light below about 850 nm, while impeding light above about 2,000 nm. As another example, the optical filter 141 could impede light below about 850 nm, while not substantially impeding light above the 905 nm wavelength of the light source 130. The optical filter 141 can be an interference filter, although any other suitable types of filter can be used (e.g., an absorption filter). By impeding light of other wavelengths from reaching the optical sensor 142, the optical filter 141 can improve the signal-to-noise ratio of the optical sensor 142 output, which can improve object detection capability and ranging accuracy of the scanner 100.

In some embodiments, the window 122 (e.g., which can have a generally frustoconical shape, although any other suitable shape could be used) can operate as an optical filter. The window 122 can permit light from the light source 130 and return reflections thereof to pass through the window 122. The window can impede other wavelengths of light from being transmitted through the window 122, for example similar to the discussion herein regarding the optical filter 141. In some embodiments, the window 122 can impede one or more wavelengths of light that are not effectively impeded by the optical filter 141. In some embodiments, the window 122 can have a dye, film or other type of filter.

The scanner 100 can have a max operational range of about 1 meter, about 2 meters, about 3 meters, about 4 meters, about 5 meters, about 6 meters, about 7 meters, about 8 meters, about 9 meters, about 10 meters, about 12 meters, about 15 meters, about 20 meters, or any values or ranges therebetween, although other ranges are possible. These ranges can be sufficient for detecting objects for machine guarding applications. In some cases, the scanner 100 can determine the distance to an object at different (e.g. longer) ranges (e.g., for range finding or other applications), such as about 25 meters, about 50 meters, about 100 meters, about 200 meters, about 300 meters, about 500 meters, about 1,000 meters, or more, or any values or ranges therebetween. In some embodiments, the operational range can be sufficiently short that the time window of the return reflection is sufficiently narrow that no triggering circuit or delay line is used, although longer ranges are also possible, which could use these features.

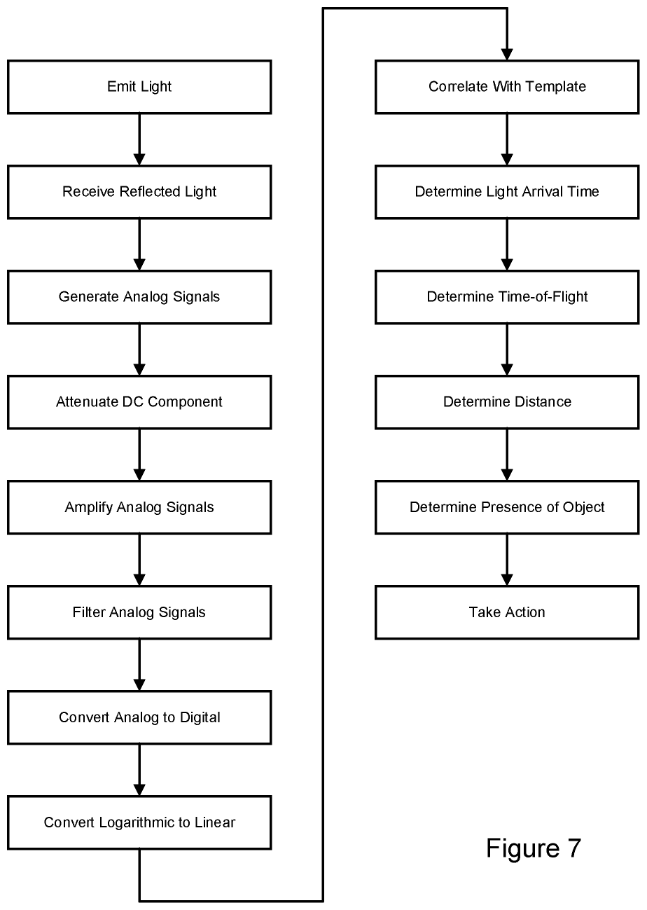

FIG. 7 is a flowchart showing an example embodiment of a method for operating a laser scanner, according to the descriptions herein. Various features disclosed herein are optional and can be omitted. The signal generator 166 and the testing technique described herein are optional and can be omitted. In some cases, the capacitor 154, amplifier 156, and/or filter can be omitted. In FIG. 7, the features of attenuating the DC component, amplifying the analog signals (e.g., using an amplifier with a logarithmic response), and converting logarithmic to linear, can be omitted. Any combination of determining the arrival time, determining the time-of-flight value, determining the distance, determining the presence of the object, and taking action can be performed or omitted, as discussed herein. The features and approaches disclosed herein can enable determination of the distance with sufficient accuracy without averaging, or otherwise combining, multiple passes on the same object. However, in some cases, the distance to an object can be determined multiple times. Those determined distances could be averaged, or otherwise combined, which can further increase the signal to noise ratio.

In some embodiments, the methods, techniques, microprocessors, and/or controllers described herein are implemented by one or more special-purpose computing devices. The special-purpose computing devices may be hard-wired to perform the techniques, or may include digital electronic devices such as one or more application-specific integrated circuits (ASICs) or field programmable gate arrays (FPGAs) that are persistently programmed to perform the techniques, or may include one or more general purpose hardware processors programmed to perform the techniques pursuant to program instructions in firmware, memory, other storage, or a combination thereof. The instructions can reside in RAM memory, flash memory, ROM memory, EPROM memory, EEPROM memory, registers, hard disk, a removable disk, a CD-ROM, or any other form of a non-transitory computer-readable storage medium. Such special-purpose computing devices may also combine custom hard-wired logic, ASICs, or FPGAs with custom programming to accomplish the techniques. The special-purpose computing devices may be desktop computer systems, server computer systems, portable computer systems, handheld devices, networking devices or any other device or combination of devices that incorporate hard-wired and/or program logic to implement the techniques.

The microprocessors or controllers described herein can be coordinated by operating system software, such as iOS, Android, Chrome OS, Windows XP, Windows Vista, Windows 7, Windows 8, Windows 10, Windows Server, Windows CE, Unix, Linux, SunOS, Solaris, macOS, Blackberry OS, VxWorks, or other compatible operating systems. In other embodiments, the computing device may be controlled by a proprietary operating system. Conventional operating systems control and schedule computer processes for execution, perform memory management, provide file system, networking, I/O services, and provide a user interface functionality, such as a graphical user interface (“GUI”), among other things.

The microprocessors and/or controllers described herein may implement the techniques described herein using customized hard-wired logic, one or more ASICs or FPGAs, firmware and/or program logic which causes microprocessors and/or controllers to be a special-purpose machine. According to one embodiment, parts of the techniques disclosed herein are performed by a controller in response to executing one or more sequences of instructions contained in a memory. Such instructions may be read into the memory from another storage medium, such as storage device. Execution of the sequences of instructions contained in the memory causes the processor or controller to perform the process steps described herein. In alternative embodiments, hard-wired circuitry may be used in place of or in combination with software instructions.

Moreover, the various illustrative logical blocks and modules described in connection with the embodiments disclosed herein can be implemented or performed by a machine, such as a processor device, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor device can be a microprocessor, but in the alternative, the processor device can be a controller, microcontroller, or state machine, combinations of the same, or the like. A processor device can include electrical circuitry configured to process computer-executable instructions. In another embodiment, a processor device includes an FPGA or other programmable device that performs logic operations without processing computer-executable instructions. A processor device can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor device may also include primarily analog components. For example, some or all of the techniques described herein may be implemented in analog circuitry or mixed analog and digital circuitry.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The words “coupled” or connected,” as generally used herein, refer to two or more elements that can be either directly connected, or connected by way of one or more intermediate elements. Additionally, the words “herein,” “above,” “below,” and words of similar import, when used in this application, shall refer to this application as a whole and not to any particular portions of this application. Where the context permits, words in the Detailed Description using the singular or plural number can also include the plural or singular number, respectively. The words “or” in reference to a list of two or more items, is intended to cover all of the following interpretations of the word: any of the items in the list, all of the items in the list, and any combination of the items in the list. All numerical values provided herein are intended to include similar values within a range of measurement error.

Although this disclosure contains certain embodiments and examples, it will be understood by those skilled in the art that the scope extends beyond the specifically disclosed embodiments to other alternative embodiments and/or uses and obvious modifications and equivalents thereof. In addition, while several variations of the embodiments have been shown and described in detail, other modifications will be readily apparent to those of skill in the art based upon this disclosure. It is also contemplated that various combinations or sub-combinations of the specific features and aspects of the embodiments may be made and still fall within the scope of this disclosure. It should be understood that various features and aspects of the disclosed embodiments can be combined with, or substituted for, one another in order to form varying modes of the embodiments. Any methods disclosed herein need not be performed in the order recited. Thus, it is intended that the scope should not be limited by the particular embodiments described above.

Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment. Any headings used herein are for the convenience of the reader only and are not meant to limit the scope.

Further, while the devices, systems, and methods described herein may be susceptible to various modifications and alternative forms, specific examples thereof have been shown in the drawings and are herein described in detail. It should be understood, however, that the disclosure is not to be limited to the particular forms or methods disclosed, but, to the contrary, this disclosure covers all modifications, equivalents, and alternatives falling within the spirit and scope of the various implementations described. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication.

The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are at standard conditions including ambient temperature and pressure.

The following is claimed:

1. A laser scanner comprising:
a laser light source configured to output laser pulses;
an optical sensor configured to generate analog signals from light of one of the laser pulses that is reflected by an object, the analog signals having a first dynamic range;
a logarithmic amplifier configured to amplify the analog signals to have a second dynamic range that is smaller than the first dynamic range;
an analog to digital converter configured to convert the analog signals to digital signal samples having a signal sample rate;
computer-readable memory having a template stored therein, wherein the template represents an expected return reflection signal, and wherein the template has a template sample rate that is higher than the signal sample rate; and
at least one processor configured to:
perform a cross-correlation between the digital signal samples and the template;
determine a time-of-flight value based at least in part on the cross-correlation; and
determine a distance to the object based at least in part on the time-of-flight value.

2. The laser scanner of claim 1, wherein the optical sensor is an avalanche photo diode.

3. The laser scanner of claim 1, further comprising a capacitor between the optical sensor and the logarithmic amplifier, wherein the capacitor is configured to attenuate direct current (DC) components of the analog signals.

4. The laser scanner of claim 1, an antialiasing filter configured to attenuate frequency content of the analog signals above a threshold frequency.

5. The laser scanner of claim 1, wherein the at least one processor is configured to convert the digital signal samples from a logarithmic scale to a linear scale.

6. The laser scanner of claim 1, wherein the signal sample rate is between about 200 million samples per second and about 1,250 million samples per second.

7. The laser scanner of claim 1, wherein the signal sample rate is between about 200 million samples per second and about 600 million samples per second.

8. The laser scanner of claim 7, wherein the at least one processor is configured to determine the distance to the object with a resolution of about 5 mm to about 75 mm.

9. The laser scanner of claim 1, wherein the signal sample rate is less than 750 million samples per second, and wherein the at least one processor is configured to determine the distance to the object with a resolution of less than about 100 mm.

10. The laser scanner of claim 1, wherein the at least one processor is configured to:
determine that an object is present at a first distance in response to a detection of light over a first light detection threshold;
determine that an object is present at a second distance in response to a detection of light over a second light detection threshold; and
determine that an object is present at a third distance in response to a detection of light over a third light detection threshold;
wherein the second distance is further than the first distance;
wherein the third distance is further than the second distance;
wherein the second light detection threshold is higher than the first light detection threshold; and
wherein the third light detection threshold is lower than the second light detection threshold.

11. The laser scanner of claim 1, wherein the at least one processor is configured to determine that an object is present at least in part by applying different light detection thresholds for different distances or distance ranges.

12. The laser scanner of claim 1, wherein the at least one processor is configured to scale at least some of the digital signal samples based at least in part on the determined distance to the object.

13. The laser scanner of claim 12, wherein the at least one processor is configured to confirm or disregard the presence of the object based at least in part on a comparison of the scaled digital signal samples to a threshold.

14. The laser scanner of claim 1, wherein the at least one processor is configured to:
determine that the object is potentially present at the determined distance;
scale at least some of the digital signal samples based at least in part on the determined distance; and
confirm the presence of the object at least in part by comparing the scaled digital signal samples to a threshold.

15. The laser scanner of claim 14, wherein the at least one processor is configured to:
apply a first gain to the at least some of the digital signal samples for a first distance;
apply a second gain to the at least some of the digital signal samples for a second distance;
apply a third gain to the at least some of the digital signal samples for a third distance;
wherein the second distance is further than the first distance;
wherein the third distance is further than the second distance;
wherein the second gain is less than the first gain; and
wherein the third gain is more than the second gain.

16. The laser scanner of claim 1, wherein the at least one processor comprises a field programmable gate array and a microcontroller.

17. The laser scanner of claim 1, further comprising a test signal generator configured to inject an analog test signal before the logarithmic amplifier, so that the logarithmic amplifier amplifies the analog test signal, and so that the analog to digital converter converts the analog test signal into a plurality of digital test signal samples, wherein the at least one processor is configured to analyze the plurality of digital test signal samples to validate the laser scanner.

18. The laser scanner of claim 17, wherein the at least one processor is configured to perform a Fourier transform on the digital test signal samples to convert the digital test signal samples to the frequency domain, and wherein the at least one processor is configured to analyze the frequency content of the digital test signal samples.

19. The laser scanner of claim 18, wherein the at least one processor is configured to compare signal energy at a fundamental frequency to signal energy at one or more harmonic frequencies to analyze the digital test signal samples.

20. The laser scanner of claim 1, further comprising an optical filter configured to permit the light of one of the laser pulses reflected by the object to be transmitted to the optical sensor, wherein the optical filter is configured to impede transmission of other wavelengths of light.

21. The laser scanner of claim 1, further comprising a window, wherein the laser light source outputs the laser pulses through the window, wherein the light of one of the laser pulses that is reflected by the object is received through the window, and wherein the window is configured to impede transmission of ambient light.

22. A method for determining a distance to an object, the method comprising:
emitting a light pulse in a direction towards an object;
receiving a return reflection of the light pulse from the object;
generating an analog signal for the return reflection using an optical sensor;
amplifying the analog signal using a logarithmic amplifier;
filtering the analog signal using an antialiasing filter;
converting the analog signal to a plurality of digital signal samples at a signal sample rate;
performing a cross-correlation between the plurality of digital signal samples and a template that has a template sample rate that is faster than the signal sample rate; and
determining a distance to the object based at least in part on the cross-correlation.

23. The method of claim 22, wherein determining the distance to the object comprises:
determining a time-of-flight value based at least in part on the cross-correlation; and
determining the distance to object based at least in part on the time-of-flight value.

24. The method of claim 22, comprising:
determining a return reflection arrival time based at least in part on the cross-correlation;
determining a time-of-flight based at least in part on the return reflection arrival time and a time that the light pulse was emitted; and
determining the distance to the object based at least in part on the time-of-flight.

25. The method of claim 22, further comprising converting the plurality of digital signal samples from a logarithmic scale to a linear scale prior to the cross-correlation.

26. The method of claim 22, wherein the cross-correlation is performed by a processor.

27. The method of claim 26, wherein the processor is in communication with computer-readable memory that store the template.

28. The method of claim 22, further comprising stopping machinery in response to detecting an object.

29. The method of claim 22, comprising determining the distance to the object with a resolution between about 10 mm and about 50 mm.

30. The method of claim 22, wherein the light pulse is a laser pulse.

31. The method of claim 22, comprising confirming the presence of the object at least in part by scaling at least some of the digital signal samples based at least in part on the determined distance and comparing the scaled digital signal samples to a threshold.

32. The method of claim 22, wherein scaling the at least some of the digital signal samples has the effect of increasing sensitivity in a short range as compared to a mid range, and increasing sensitivity in a long range as compared to the mid range.

33. The method of claim 22, comprising applying different light detection thresholds for different distance ranges to determine presence of an object.

34. The method of claim 22, comprising:
comparing light reflected from a first distance to a first light detection threshold to determine whether an object is present at the first distance;
comparing light reflected from a second distance to a second light detection threshold to determine whether an object is present at the second distance; and
comparing light reflected from a third distance to a third light detection threshold to determine whether an object is present at the third distance;
wherein the second distance is further than the first distance;
wherein the third distance is further than the second distance;
wherein the second light detection threshold is higher than the first light detection threshold; and
wherein the third light detection threshold is lower than the second light detection threshold.

35. The method of claim 22, further comprising:
injecting an analog test signal;
amplifying the analog test signal using the logarithmic amplifier;
filtering the analog test signal using an antialiasing filter;
converting the analog test signal to a plurality of digital test signal samples; and
analyzing the plurality of digital test signal samples for validation.

36. The method of claim 35, comprising analyzing the plurality of digital test signal samples in the frequency domain.

37. The method of claim 35, further comprising performing a Fourier transform on the plurality of digital test signal samples.

38. A laser scanner comprising:
a laser light source configured to output laser light;
an optical sensor for generating analog signals from return reflections of the laser light that is reflected by objects;
an analog to digital converter configured to convert the analog signals to digital signal samples; and
a processor configured to process the digital signal samples to determine time-of-flight information.

39. The laser scanner of claim 38, further comprising an amplifier for amplifying the analog signals.

40. The laser scanner of claim 39, wherein the amplifier is a logarithmic amplifier.

41. The laser scanner of claim 40, wherein the processor is configured to convert the digital signal samples from a logarithmic scale to a linear scale.

42. The laser scanner of claim 39, wherein the amplifier has a soft saturation characteristic.

43. The laser scanner of claim 38, wherein the processor is configured to compare the digital signal samples to a template, wherein the time-of-flight information is based at least in part on the comparison.

44. The laser scanner of claim 43, wherein the comparison is a cross-correlation.

45. The laser scanner of claim 38, wherein the processor is configured to determine a distance to the object based at least in part on the time-of-flight information.

46. A laser scanner comprising:
an optical sensor configured to generate analog signals
an analog to digital converter configured to convert the analog signals to digital signal samples having a signal sample rate between about 200 million samples per second and about 600 million samples per second; and
and a processor configured to analyze the digital signal samples to determine a distance to an object with a distance resolution of about 5 mm to about 75 mm.
